(19) United States
(12) Patent Application Publication
(10) Pub. No.: US 2004/0022943 A1
(43) Pub. Date: Feb. 5, 2004

(54) Carbon nanotube tweezer and a method of producing the same

(76) Inventor: Rudiger Schlaf, Lutz, FL (US)

Correspondence Address: The Pinehurst Office Center, Suite #101, 39400 Woodward Avenue, Bloomfield Hills, MI, 48304-5151, US

(21) Appl. No.: 10/413,597

(22) Filed: Apr. 14, 2003

Related U.S. Application Data
(60) Provisional application No. 60/319,182, filed on Apr. 12, 2002.

(51) Int. Cl. C23C 16/00; C23C 16/32

(52) U.S. Cl. 427/249.1

(57) ABSTRACT

A carbon nanotube (CNT) tweezer and a method of producing the tweezer are disclosed. The tweezer includes a tip formed from an insulator, and first and second CNT prongs. The first prong extends from a surface of the tip, and the second prong is spaced from the first prong and extends from the surface of the tip generally parallel to the first prong. The prongs are grown from a catalyst. A first patch of the catalyst is deposited onto the surface and a second patch of the catalyst onto the surface and spaced from the first patch. The catalyst is subjected to chemical vapor deposition to initiate growth of the prongs. The prongs extend from the tip with a distance between ends of the prongs. The prongs are bent toward one another thereby decreasing the distance between the ends such that the small particle is grasped therebetween and can be micro-manipulated.

### RELATED APPLICATIONS

This patent application claims priority to and all advantages of U.S. Provisional Patent Application No. 60/319,182, which was filed on Apr. 12, 2002.

### BACKGROUND OF THE INVENTION

1. Field of the Invention

The subject invention generally relates to a carbon nanotube (CNT) tweezer for the micro-manipulation of a small particle and a method of producing the CNT tweezer. More specifically, the CNT tweezer includes carbon nanotube prongs that are grown, via chemical vapor deposition, from patches of catalytic material deposited on a surface of a tip of the tweezer.

2. Description of the Related Art

The related art includes CNT tweezers and also includes known methods of producing the CNT tweezers. It is known that the CNT tweezers specifically include individual CNT prongs to micro-manipulate a small particle. The tweezers and method of the related art are deficient in that they require separate fabrication of the CNT prongs. That is, these conventional tweezers and methods manually attach the CNT prongs, which has been previously grown elsewhere, using some form of a micro-manipulator in combination with an optical microscope. Such manual requirements are extremely burdensome and slow. Therefore, the tweezers and methods of the prior art are only suitable for the preparation of a limited number of CNT tweezers that are primarily used in testing and experimentation.

The related art is characterized by one or more inadequacy, including those described above. Therefore, it would be advantageous to provide a CNT tweezer that can be mass produced and a method of producing the CNT tweezer that enables this mass production. It would also be advantageous to provide a CNT tweezer and method of producing the CNT tweezer that eliminates any need for the separate fabrication of the CNT prongs.

### SUMMARY OF THE INVENTION AND ADVANTAGES

A carbon nanotube (CNT) tweezer and a method of producing the CNT tweezer are disclosed. The tweezer is used for micro-manipulation of a small particle. The tweezer includes a tip formed from an insulating material, a first CNT prong, and a second CNT prong. The first CNT prong extends from a surface of the tip, and the second CNT prong is spaced from the first CNT prong and extends from the surface of the tip generally parallel to the first CNT prong. The first and second CNT prongs are grown from a catalytic material, which may, or may not, be the same.

A first patch of the catalytic material is deposited onto the surface of the tip, and a second patch of the catalytic material is deposited onto the surface of the tip spaced from the first patch. Next, the catalytic material is subjected to chemical vapor deposition to initiate growth of the first and second CNT prongs. As such, the first and second CNT prongs extend from the tip with a distance between ends of the first and second CNT prongs.

At least one of the first CNT prong and the second CNT prong is bent toward the other of the first CNT prong and the second CNT prong, which decreases the distance between the ends of the first and second CNT prongs. As such, the small particle is grasped between the first and second CNT prongs and can be micro-manipulated.

Accordingly, the subject invention overcomes the inadequacies of the related art by providing a CNT tweezer that can be mass produced and method of producing the CNT tweezer. By growing the CNT prongs via chemical vapor deposition from patches of the catalytic material that have been deposited on the surface of the tip, the CNT tweezer and the method of the subject invention eliminate any need for the separate fabrication of the CNT prongs. Without the requirement for separate fabrication of the CNT prongs, the CNT tweezer can be mass produced.

### BRIEF DESCRIPTION OF THE DRAWINGS

Other advantages of the present invention will be readily appreciated as the same becomes better understood by reference to the following detailed description when considered in connection with the accompanying drawings wherein:

FIG. 1A is a side view of a carbon nanotube tweezer produced according to the method of the subject invention including a first carbon nanotube prong and a second carbon nanotube prong;

FIG. 1B is a side view of the carbon nanotube tweezer of FIG. 1A illustrating the first and second carbon nanotube prongs realizing an applied voltage and bending toward one another to grasp a small particle for micro-manipulation of the small particle; and

FIG. 2 is a view of the carbon nanotube tweezer in combination a piezo scanner for moving and positioning the small particle.

### DETAILED DESCRIPTION OF THE PREFERRED EMBODIMENT

Referring to the Figures, wherein like numerals indicate like or corresponding parts throughout the several views, a method for producing a carbon nanotube (CNT) tweezer, or tweezers, 10 is disclosed. The CNT tweezer 10 is used for micro-manipulation of a small particle 12 or cluster. The particular type of small particle 12 is not pertinent and does not vary the scope of the subject invention. Examples of small particles 12 that can be micro-manipulated with the CNT tweezer 10 of the subject invention include, but are not limited to, various nano-particles, various pathogens, e.g. anthrax, proteins, and enzymes. Also, the CNT tweezer 10 may be used to micro-manipulate a plurality of small particles 12 without varying the scope of the subject invention. In other words, the CNT tweezer 10 is not limited to micro-manipulating only one small particle 12 at a time.

The CNT tweezer 10 includes a tip 14 formed from an insulating material, a first CNT prong 16 and a second CNT prong 18. The particular insulating material used is not critical so long as the tip 14 is insulated. An example of a suitable tip 14 is a Si tip 14 with an insulating oxide layer about the tip 14. The first CNT prong 16 extends from a surface 20 of the tip 14 of the CNT tweezer 10. The second CNT prong 18 is spaced from the first CNT prong 16 and extends from the surface 20 of the tip 14 generally parallel to the first CNT prong 16. Both the first CNT prong 16 and the second CNT prong 18 are grown from a catalytic material 22. Throughout the description herein, the catalytic material 22 may also be referred to as catalyst 22 and catalyst material 22. Preferably, the catalytic material 22 is selected from the group consisting of nickel, cobalt, iron, and combinations thereof.

The method of the subject invention includes the step of depositing a first patch 24 of the catalytic material 22 onto the surface 20 of the tip 14 and depositing a second patch 26 of the catalytic material 22 onto the surface 20 of the tip 14. The first and second patches 24, 26 can be deposited at the same, or different, times. The second patch 26 is spaced from the first patch 24. Preferably, the first and second patches 24, 26 of catalytic material 22 are deposited onto the surface 20 of the tip 14 using a focused ion beam (FIB) deposition technique. The FIB deposition technique is understood by those skilled in the art.

In one particular alternative embodiment, the subject invention may further include the step of depositing a sensitizing material onto the surface 20 of the tip 14 prior to depositing the first and second patches 24, 26 of catalytic material 22. If the sensitizing material is utilized, as in this embodiment, it is depositing by the FIB deposition technique. In this alternative embodiment, the first and second patches 24, 26 of catalytic material 22 are deposited on top of the sensitizing material using electroless plating, instead of the FIB deposition technique. More specifically, the sensitizing material sensitizes the electroless plating process, which is chemically tuned not to coat the bare tip 14. After the FIB deposition of the sensitizing material, the catalyst 22 is electrolessly deposited on top of the sensitizing material but not on the other parts of the tip 14. Then, chemical vapor deposition (CVD) or plasma enhanced CVD (PECVD) are used to grow the first and second CNT prongs 16, 18 as described immediately below.

Next, the catalytic material 22, specifically the first patch 24 and the second patch 26, is subjected to, i.e., exposed to, CVD to initiate growth of the first CNT prong 16 and the second CNT prong 18. As such, the first CNT prong 16 and the second CNT prong 18 extend from the tip 14 with adistance, D, between ends 28 of the first and second carbon nanotube prongs 16, 18. As a result, the second CNT prong 18 is spaced from the first CNT prong 16. The first CNT prong 16 is grown from the first patch 24 and the second CNT prong 18 is grown from the second patch 26. It is to be understood that, preferably, the catalytic material 22 that is used for the first and second patches 24, 26 is the same. However, in alternative embodiments, the catalytic material 22 that is used for the first patch 24, i.e., a first catalytic material, may be different than the catalytic material 22 that is used for the second patch 26, i.e., a second catalytic material, so long as both catalytic materials are catalysts for the grown of both CNT prongs 16, 18. Depositing the catalytic material 22 onto the surface 20 of the tip 14 and then subjecting this catalytic material 22 to CVD to initiate growth enables mass production of the CNT tweezer 10 as compared to the separate fabrication of CNT prongs.

CVD is a chemical reaction that transforms gaseous molecules, called precursors, into a solid material, in the form of thin film. Many different precursors may be utilized with the subject invention. Common gaseous precursors are selected from the group consisting of hydrides, halides, metal-organics, and combinations. The gaseous precursors suitable for use with the present invention are not limited to those listed above. Suitable metal-organics include, but are not limited to, metal alkyls, metal alkoxides, metal dialkylamides, metal diketonates, or metal carbonyls, and combinations thereof.

The CVD is carried out in a reactor. Most reactors include gas and vapor delivery lines, a reactor main chamber having a hot wall and a cold wall. The reactor also includes substrate loading and unloading assembly for positioning the substrate within the reactor.

The reactor also includes an energy source(s). Typical examples of energy sources include resistive heating, radiant heating, and inductive heating. Resistive heating includes energy from a tube furnace or a quartz tungsten halogen lamp. Radiant heating provides energy from radio-frequency and inductive heating provided energy from a laser as a thermal energy source. Yet another energy source is photo energy from an UV-visible light laser.

The products from the CVD include a solid and a gas product. The solid gas products include thin films and powders. The thin films may be metals, alloys, ceramics and polymeric materials. The gas products are volatile byproducts and are always formed. The gas products generated in CVD processes are usually hazardous and must be disposed of accordingly.

Another type of CVD is PECVD. PECVD is performed in a reactor at temperatures up to ˜1000° C. The deposited film is a product of a chemical reaction between the source gases supplied to the reactor. A plasma is generated in the reactor to increase the energy available for the chemical reaction at a given temperature. The system for carrying out the PECVD is similar to that described above for CVD.

At least one of the first CNT prong 16 and the second CNT prong 18 is then bent toward the other of the first CNT prong 16 and the second CNT prong 18. As such, the distance, D, between the ends of the first and second carbon nanotube prongs 16, 18 is decreased such that the small particle 12 is grasped between the first and second carbon nanotube prongs 16, 18 and can be micro-manipulated. It is only required that one CNT prong bends toward the other CNT prong. However, as disclosed in the Figures, it is preferred that both the first CNT prong 16 and the second CNT prong 18 bend toward one another 16, 18 for the micro-manipulation of the small particle 12. For descriptive purposed only, the subject invention is described as if the first CNT prong 16 and the second CNT prong 18 bend toward one another. It is contemplated that at least one of the first CNT prong 16 and the second CNT prong 18 can be bent toward the other of the first CNT prong 16 and the second CNT prong 18 by a variety of mechanisms. However, only the most preferred mechanism for bending the CNT prongs 16, 18 toward one another 16, 18 is described immediately below.

To bend the first and second CNT prongs 16, 18 toward one another 16, 18, the subject method invention incorporates the step of patterning a first electrode 30 and a second electrode 32 on the surface 20 of the tip 14. The first and second electrodes 30, 32 function to connect the tip 14 of the CNT tweezer 10 to the macroscopic environment. As understood by those skilled in the art, the first electrode 30 and the second electrode 32 can be patterned on the surface 20 of the tip 14 before depositing the first and second patches 24, 26 of catalytic material 22 or after depositing the first and second patches 24, 26 of catalytic material 22.

In the preferred embodiment, where the first electrode 30 and the second electrode 32 are patterned on the surface 20 of the tip 14 before depositing the first and second patches 24, 26 of catalytic material 22, the step of depositing the first and second patches 24, 26 of catalytic material 22 is further defined as depositing the first patch 24 of the catalytic material 22 onto the surface 20 of the tip 14 in electrical connection with the first electrode 30 and depositing the second patch 26 of the catalytic material 22 onto the surface 20 of the tip 14 in electrical connection with the second electrode 32. As a result, the first electrode 30 is electrically-connected to the first CNT prong 16 and the second electrode 32 electrically-connected to the second CNT prong 18.

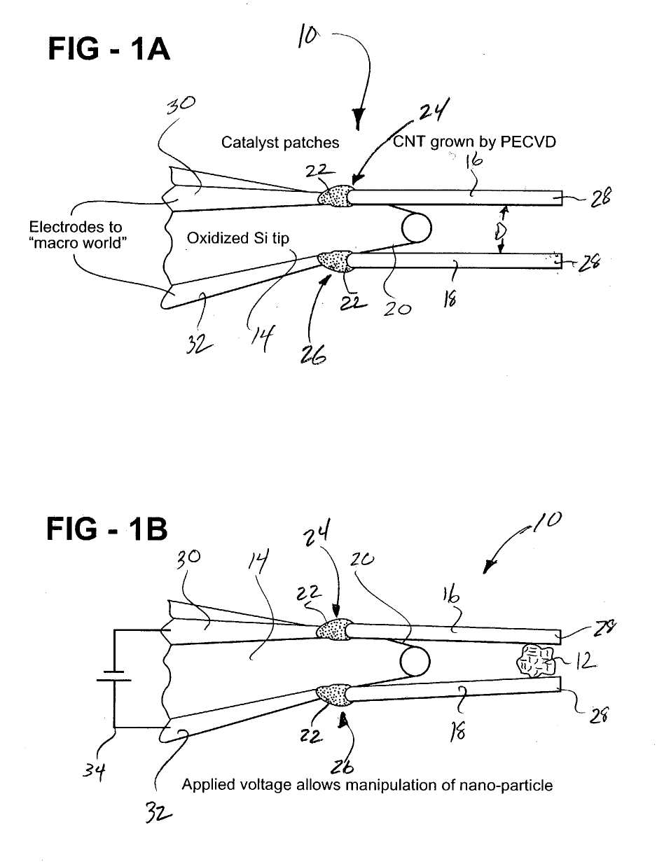

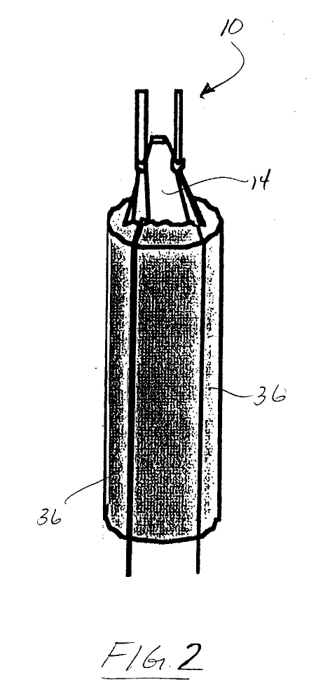

With the first and second patches 24, 26 of catalytic material 22 deposited onto the surface 20 of the tip 14 in electrical connection with the first and second electrodes 30, 32, respectively, the first and second CNT prongs 16, 18 are then bent toward one another 16, 18. More specifically, in this preferred embodiment, to bend the first and second CNT prongs 16, 18 toward one another 16, 18, a voltage is applied between the first electrode 30 and the second electrode 32. The applied voltage results in an attraction between the first and second CNT prongs 16, 18. As such, the first and second CNT prongs 16, 18 bend toward one another 16, 18 to grasp the small particle 12 therebetween. Of course, a power source 34 (represented schematically in FIG. 1B) is incorporated in the subject invention for applying the voltage between the first and second electrodes 30, 32.

In the alternative embodiment, where the first electrode 30 and the second electrode 32 are patterned on the surface 20 of the tip 14 after depositing the first and second patches 24, 26 of catalytic material 22, the first electrode 30 is patterned to be electrically-connected with the first patch 24 of catalytic material 22 and the second electrode 32 is patterned to be electrically-connected with the second patch 26 of catalytic material 22. With the first and second electrodes 30, 32 patterned to be electrically-connected with the first and second patches 24, 26 of catalytic material 22, respectively, the first and second CNT prongs 16, 18 are then bent toward one another 16, 18. More specifically, in this alternative embodiment, to bend the first and second CNT prongs 16, 18 toward one another 16, 18, the power source 34 applies a voltage between the first electrode 30 and the second electrode 32. The applied voltage results in an attraction between the first and second CNT prongs 16, 18. As such, the first and second CNT prongs 16, 18 bend toward one another 16, 18 to grasp the small particle 12 therebetween.

Even prior to the bending of the first and second CNT prongs 16, 18 toward one another 16, 18, an angle that the first and second CNT prongs 16, 18 grow at relative to the tip 14 can be selectively controlled. This step may be necessary depending on the particular small particle 12 that the CNT tweezer 10 is designed to micro-manipulate. More specifically, to control this angle, an electric field is applied as the catalytic material 22 is subjected to CVD.

The diameter of the first and second CNT prongs 16, 18 and the number of walls present in each CNT prong 16, 18 may also be controlled. To control these features of the CNT prongs 16, 18, an amount of the catalytic material 22 that is deposited for each patch 24, 26 is controlled. This varies the diameter of the CNT prongs 16, 18 and can also vary the number of walls of the CNT prongs 16, 18. Furthermore, a length of the CNT prongs 16, 18 can also be varied. To vary the length of the CNT prongs 16, 18, a duration of the CVD, or PECVD, is controlled.

The subject invention may also include the step of increasing the rigidity of the first and second CNT prongs 16, 18 that extend from the tip 14. Using the FIB deposition technique, a suitable material, for example Pt, is deposited around the areas where the CNT prongs 16, 18 are attached to the tip 14. This suitable material is deposited prior to deposition of the first and second patches 24, 26 of catalytic material 22 onto the surface 20. The suitable material enhances the mechanical attachment of the CNT prongs 16, 18 to the surface 20 of the tip 14 and enhances the lifetime of the CNT prongs 16, 18 during the micro-manipulation of the small particle 12 or particles 12.

For moving and positioning of the CNT tweezer 10, the CNT tweezer 10 produced according to the method of the subject invention could be attached to a scanning probe microscope, such as a piezo scanner assembly 36 in combination with stepper motors. Another option would be to use a micro-manipulator such as the micro-manipulator commercially available from Omniprobe of Dallas, Tex. Such mechanisms would allow the moving and positioning of the CNT tweezer 10 relative the small particle 12 that is to grasped and micro-manipulated. Once the small particle 12 has been grasped, it could be moved to a different position by the micro-manipulator or the like, and then dropped to a new position, such as a support or substrate, by ceasing application of the voltage. More specifically, upon stopping the voltage, the first and second CNT prongs 16, 18 would return to their original extended position and the small particle 12 would be dropped. Furthermore, monitoring of the micro-manipulation process could be carried out with a scanning electron microscope by placing the CNT tweezer 10 inside a vacuum chamber.

Obviously, many modifications and variations of the present invention are possible in light of the above teachings. The invention may be practiced otherwise than as specifically described within the scope of the appended claims.

What is claimed is:

1. A method of producing a carbon nanotube tweezer for micro-manipulation of a small particle, wherein the tweezer includes a tip formed from an insulating material, a first carbon nanotube prong extending from a surface of the tip, and a second carbon nanotube prong spaced from the first carbon nanotube prong and extending from the surface of the tip generally parallel to the first carbon nanotube prong, wherein the first and second carbon nanotube prongs are grown from a catalytic material, said method comprising the steps of:
depositing a first patch of the catalytic material onto the surface of the tip and a second patch of the catalytic material onto the surface of the tip spaced from the first patch;
subjecting the catalytic material to chemical vapor deposition to initiate growth of the first and second carbon nanotube prongs such that the first and second carbon nanotube prongs extend from the tip with a distance between ends of the first and second carbon nanotube prongs; and
bending at least one of the first carbon nanotube prong and the second carbon nanotube prong toward the other of the first carbon nanotube prong and the second carbon nanotube prong thereby decreasing the distance between the ends of the first and second carbon nanotube prongs such that the small particle is grasped between the first and second carbon nanotube prongs and can be micro-manipulated.

2. A method as set forth in claim 1 further comprising the step of patterning a first electrode and a second electrode on the surface of the tip.

3. A method as set forth in claim 2 wherein the step of patterning the first electrode and the second electrode on the surface of the tip is further defined as patterning the first electrode and the second electrode on the surface of the tip before depositing the first and second patches of catalytic material.

4. A method as set forth in claim 3 wherein the step of depositing the first and second patches of catalytic material is further defined as depositing the first patch of the catalytic material onto the surface of the tip in electrical connection with the first electrode and depositing the second patch of the catalytic material onto the surface of the tip in electrical connection with the second electrode.

5. A method as set forth in claim 4 wherein the step of bending at least one of the first carbon nanotube prong and the second carbon nanotube prong toward the other of the first carbon nanotube prong and the second carbon nanotube prong is further defined as applying a voltage between the first electrode and the second electrode such that the first and second carbon nanotube prongs bend toward one another to grasp the small particle therebetween.

6. A method as set forth in claim 2 wherein the step of patterning the first electrode and the second electrode on the surface of the tip is further defined as patterning the first electrode and the second electrode on the surface of the tip after depositing the first and second patches of catalytic material, such that the first electrode is patterned to be electrically-connected with the first patch of catalytic material and the second electrode is patterned to be electrically-connected with the second patch of catalytic material.

7. A method as set forth in claim 6 wherein the step of bending at least one of the first carbon nanotube prong and the second carbon nanotube prong toward the other of the first carbon nanotube prong and the second carbon nanotube prong is further defined as applying a voltage between the first electrode and the second electrode such that the first and second carbon nanotube prongs bend toward one another to grasp the small particle therebetween.

8. A method as set forth in claim 1 wherein the step of depositing the first and second patches of catalytic material is further defined as depositing a catalytic material selected from the group consisting of nickel, cobalt, iron, and combinations thereof.

9. A method as set forth in claim 1 wherein the step of subjecting the catalytic material to chemical vapor deposition comprises the step of transforming a gaseous precursor selected from the group consisting of hydrides, halides, metal-organics, and combinations thereof into a solid material.

10. A method as set forth in claim 1 wherein the step of subjecting the catalytic material to chemical vapor deposition is further defined as subjecting the catalytic material to plasma enhanced chemical vapor deposition.

11. A method as set forth in claim 1 wherein the step of depositing the first and second patches of catalytic material is further defined as depositing the first and second patches of catalytic material using focused ion beam deposition.

12. A method as set forth in claim 1 further comprising the step of depositing a sensitizing material onto the surface of the tip prior to depositing the first and second patches of catalytic material.

13. A method as set forth in claim 12 wherein the step of depositing the first and second patches of catalytic material is further defined as depositing the first and second patches of catalytic material on top of the sensitizing material using electroless plating.

14. A method as set forth in claim 1 further comprising the step of controlling an angle that the first and second carbon nanotube prongs grow at relative to the tip.

15. A method as set forth in claim 14 wherein the step of controlling the angle that the first and second carbon nanotube prongs grow at is further defined as applying an electric field as the catalytic material is subjected to chemical vapor deposition.

16. A method as set forth in claim 1 wherein the step of depositing the first and second patches of catalytic material comprises the step of controlling an amount of the catalytic material that is deposited for each patch to vary at least one of a diameter of the first and second carbon nanotube prongs and a number of walls present in the first and second carbon nanotube prongs.

17. A method as set forth in claim 1 wherein the step of subjecting the catalytic material to chemical vapor deposition comprises the step of controlling a duration of the chemical vapor deposition to vary a length of the first and second carbon nanotube prongs.

18. A method as set forth in claim 1 further comprising the step of increasing the rigidity of the first and second carbon nanotube prongs that extend from the tip.

19. A method as set forth in claim 18 wherein the step of increasing the rigidity of the first and second carbon nanotube prongs is further defined as depositing platinum onto the surface of the tip prior to depositing the first and second patches of catalytic material onto the surface.

20. A carbon nanotube tweezer for micro-manipulation of a small particle, said tweezer comprising:
a tip formed from an insulating material;
a first carbon nanotube prong grown from a patch of a first catalytic material deposited on a surface of said tip; and
a second carbon nanotube prong grown from a patch of a second catalytic material deposited on said surface of said tip, wherein said second carbon nanotube prong is spaced from said first carbon nanotube prong and extends from said surface of said tip generally parallel to said first carbon nanotube prong.

21. A carbon nanotube tweezer as set forth in claim 20 wherein said first and second catalytic materials are selected from the group consisting of nickel, cobalt, iron, and combinations thereof.

22. A carbon nanotube tweezer as set forth in claim 20 wherein said first and second catalytic material are the same.

23. A carbon nanotube tweezer as set forth in claim 20 wherein said first and second carbon nanotube prongs are grown by subjecting said first and second catalytic materials to chemical vapor deposition.

24. A carbon nanotube tweezer as set forth in claim 20 further comprising a first electrode electrically-connected to said first carbon nanotube prong and a second electrode electrically-connected to said second carbon nanotube prong.

25. A carbon nanotube tweezer as set forth in claim 24 further comprising a power source electrically-connected to said first and second electrodes for applying a voltage between said first and second electrodes such that said first and second carbon nanotube prongs bend toward one another to grasp the small particle therebetween.
